(19) United States
(12) Patent Application Publication
(10) Pub. No.: US 2007/0247189 A1
(43) Pub. Date: Oct. 25, 2007

(54) FIELD PROGRAMMABLE SEMICONDUCTOR OBJECT ARRAY INTEGRATED CIRCUIT

(75) Inventors: Doug Phil, Portland, OR (US); Ronald K. Bell, Forest Grove, OR (US); Kevin E. Atkinson, Madison Lake, MN (US); David Trawick, Plano, TX (US); Fuk Ho Pius Ng, Plano, TX (US); Liem T. Nguyen, Plano, TX (US)

Correspondence Address: STOEL RIVES LLP, 900 SW FIFTH AVENUE, SUITE 2600, PORTLAND, OR, 97204-1268, US

(73) Assignee: MathStar, Hillsboro, OR (US)

(21) Appl. No.: 11/567,146

(22) Filed: Dec. 5, 2006

Related U.S. Application Data
(63) Continuation-in-part of application No. 11/042,547, filed on Jan. 25, 2005.

(51) Int. Cl. H03K 19/177

(52) U.S. Cl. 326/41

(57) ABSTRACT

A field-programmable object array integrated circuit employs a course gain architecture comprising a core array of highly optimized silicon objects that are individually programmed and synchronously connected via high performance parallel communications structures permitting the user to configure the device to implement a variety of very high performance algorithms. The high level functions available in the objects combined with the unique interconnect structures enables performance superior to existing field programmable solutions while maintaining and enhancing the flexibility. A consistent peripheral “donut” structure around the core of each object makes them interchangeable to build up complex circuits without redesign of standard objects.

### RELATED APPLICATIONS

This application is a continuation-in-part of co-pending U.S. patent application Ser. No. 11/042,547 filed Jan. 25, 2005 and entitled, “INTEGRATED CIRCUIT LAYOUT HAVING RECTILINEAR STRUCTURE OF OBJECTS,” incorporated herein by this reference. Commonly-owned U.S. Pat. No. 6,816,562 dated Nov. 9, 2004 also is incorporated herein in its entirety by this reference.

### COPYRIGHT NOTICE

© 2005-2006 MathStar, Inc. A portion of the disclosure of this patent document contains material that is subject to copyright protection. The copyright owner has no objection to the facsimile reproduction by anyone of the patent document or the patent disclosure, as it appears in the Patent and Trademark Office patent file or records, but otherwise reserves all copyright rights whatsoever. 37 CFR § 1.71(d).

### TECHNICAL FIELD

The present invention relates to design and verification of circuit layouts, and more particularly to methods and apparatus for design of objects and for communication between and among objects in a semiconductor object array to implement a wide variety of functionality.

### BACKGROUND OF THE INVENTION

The transistor density in integrated circuit technology continues to increase; however, the increase in processing potential made possible by the increased transistor density is limited, in part, due to high development complexity, time and costs. As transistor technology advances, cost and complexity of application specific integrated circuit (ASIC) development continues to increase. Field Programmable Gate Array (FPGA) technology provides a lower cost solution, but lacks the performance. Reconfigurable computing has been viewed as a possible remedy for balancing the costs and performance requirements of complicated applications.

As process geometry becomes smaller, problems of physical timing-closure and other physical effects such as cross-talking, electromigration and the like become dominant design problems because they require significant resources to identify and overcome. Since the cost of design and verification is proportional to the time of the design and verification process, reducing the design time will reduce the cost.

The need remains for a highly flexible and configurable structure to implement various functions and operations in an object array without customization of the objects. Rather, each type of object can be optimized once and reused in a variety of applications. Embodiments of the present invention provide solutions to these and other problems, and offer other advantages over the prior art.

### SUMMARY OF THE INVENTION

An integrated circuit layout pattern is formed from a plurality of objects placed within the layout pattern. In general, the layout pattern defines and is used for design and manufacture of a field-programmable, semiconductor integrated circuit device. In presently preferred embodiments, such devices comprise a core region and a periphery region. The core region contains one or more silicon objects, also called core objects, which provide various logical or computational functions (generally referred to herein as “logic circuitry”). Preferably, at least some of the objects are individually programmable. The present invention is not limited to the use of any particular core object or objects in terms of their specific logical or computational functions. Rather, the present invention relates to object structures and communications and cooperation between and among such core objects, so as to facilitate assembling numerous such core objects together in a single chip to implement complex or high-performance functionality. In this context, core objects can implement logic circuitry either independently or cooperatively with other core objects in the array.

The present invention in one aspect provides a consistent or homogenous communications interface for coupling a core object to other core objects, and/or to a periphery circuit block. Through the use of a consistent communications interface, core objects can be incorporated as needed for any specific application, without having to modify or redesign any of the individual core objects. The core objects cooperate together so as to form a configurable communications fabric, thus facilitating rapid design and implementation of higher level functionality because the communication fabric can be configured as needed, again without customizing core objects. The communication fabric is synchronous, at least locally. Timing is fully deterministic throughout the device, and timing closure is greatly simplified by the discrete communication “hops” implemented by the communication fabric.

Periphery circuit blocks are disposed in the periphery region, which in general can be any area of the chip that is outside of the core region. In a presently preferred embodiment, the periphery region conveniently is arranged generally surrounding the core region. In general, the periphery region, as the name implies, is conveniently located along at least a portion of the edges of the chip as it implements external connections to the chip. At least some of the periphery blocks preferably are coupled to the communication elements of a core object so as to extend the communication fabric from the core region into the periphery block.

Each core object, in addition to its logic circuitry, includes various supporting structures to provide for programming, clock synchronization, and communications with other objects. That is, each object implements pre-designed structures or resources that form part of the larger communication fabric, clock distribution, BIST and the like, simply by insertion of the object into the array. These resources can be thought of as a logical or virtual “donut” surrounding the logic circuitry of an object, although they need not be implemented in any particular shape or arrangement, with one exception: the supporting structures must implement a predetermined, consistent arrangement of connections along one or more peripheral edges of the object for interconnection with other objects.

In the description below, by way of illustration and not limitation, we provide some examples in which a core object comprises a rectilinear “donut” structure physically surrounding a central logic area of the object. One important aspect of the donut are the communications elements. These communication elements implement the communication fabric mentioned above. It has two main aspects—“nearest neighbor” communications and “party line” communications. The former refer primarily to communications between neighboring or adjacent core objects, although Nearest Neighbor communications can extend to periphery blocks as well. Party Line structures are used for communications among non-adjacent (or “remote”) core objects, as well as communications with periphery blocks.

In one embodiment, all of the core objects in an array have a consistent rectilinear shape so as to enable insertion of the core objects into the array via abutment. Further, the communication elements of multiple core objects preferably form the inter-object communication fabric simply by abutting insertion into the array. In this way, desired inter-object communications can be realized by software configuration of object resources to form buses as needed, rather than custom hardware design or modification.

Additional aspects and advantages will be apparent from the following detailed description of preferred embodiments, which proceeds with reference to the accompanying drawings.

### BRIEF DESCRIPTION OF THE DRAWINGS

FIG. 1 is a simplified block diagram of a silicon object according to an embodiment of the present invention.

FIG. 2 is a simplified block diagram of a regular array of silicon objects of FIG. 1 according to an embodiment of the present invention.

FIG. 3 is a simplified block diagram of elements of a homogenous communications structure or donut of a silicon object according to an embodiment of the present invention.

FIG. 4 is a more detailed block diagram of selected elements of the homogenous communications structure or donut of FIG. 3.

FIG. 5 is a screen shot of example of a silicon object layout.

FIG. 6A is a simplified block diagram of an array of silicon objects with interconnecting communication elements of neighboring donuts identified according to an embodiment of the present invention.

FIG. 6B is an expanded, simplified block diagram illustrating interconnection of silicon objects by abutment in a layout pattern according to an embodiment of the present invention.

FIG. 7 is a screen shot of a portion of an object array in a graphical user interface of a computer layout design program according to an embodiment of the present invention.

FIG. 8 is a simplified block diagram of a silicon object with a homogenous communications structure or donut including a clock ring according to an embodiment of the present invention.

FIG. 9A is simplified block diagram of an array of silicon objects with a clock spine and power rib and mesh overlaid according to an embodiment of the present invention.

FIG. 9B is an expanded simplified block diagram of a two-by-two object portion of the array of FIG. 9A showing the interconnections between clock rings within the array according to an embodiment of the present invention.

FIG. 10 is a simplified block diagram of silicon object array illustrating data flow from a neighboring silicon object according to an embodiment of the present invention.

FIG. 11 is a simplified block diagram of a silicon object with a homogenous communications structure or donut containing a clock ring and power mesh according to an embodiment of the present invention.

FIG. 12 is a simplified block diagram of an individual silicon object showing selected elements of one embodiment of a standardized communication interface and other features of the donut region surrounding the object core.

FIG. 13 is a simplified block diagram of two adjacent core objects and two periphery blocks showing examples of communication connections.

FIG. 14 is a simplified conceptual diagram of an individual core object illustrating Nearest Neighbor and Party Line communication channels in a presently preferred embodiment.

FIG. 15 is a simplified conceptual diagram of an individual core object illustrating Nearest Neighbor communication output paths in a presently preferred embodiment.

FIG. 16 is a simplified conceptual diagram of neighboring silicon objects surrounding a current object illustrating Nearest Neighbor communication input paths in a presently preferred embodiment.

FIG. 17 is a simplified conceptual diagram of an individual silicon object illustrating Nearest Neighbor routing in a presently preferred embodiment.

FIG. 18 is a simplified block diagram illustrating one example of an FPOA having a central array of core objects and a periphery region in which various periphery blocks are shown.

FIG. 19 is a simplified conceptual illustration of Party Line and Nearest Neighbor communications paths among objects in the array of FIG. 18.

FIG. 20 is a simplified conceptual illustration of hop distances among objects in the array of FIG. 18 for synchronization.

While the above-identified illustrations set forth preferred embodiments of the present invention, other embodiments are also contemplated, some of which are noted in the discussion. In all cases, this disclosure presents the illustrated embodiments of the present invention by way of representation and not limitation. Numerous other minor modifications and embodiments can be devised by those skilled in the art which fall within the scope and spirit of the principles of this invention.

### DETAILED DESCRIPTION OF PREFERRED EMBODIMENTS

### Overview

A field-programmable object array or FPOA is a medium grain architecture comprising highly optimized silicon objects that are individually programmed and synchronously interconnected via high performance parallel communications structures, permitting the user to configure the device to implement a variety of very high performance algorithms. The high level functions available in the objects combined with the unique interconnect structure enables performance superior to existing field programmable solutions while maintaining and enhancing the flexibility.

Aspects of the invention include but are not limited to the following: Optimized silicon object architecture with abutment design, synchronous array of silicon objects, combined Nearest Neighbor and Party Line inter-object communications, predictable place and route timing, object level power control, and object-level end user programmability.

In general, an FPOA can be described as a massively parallel, user programmable, semiconductor structure comprising a set of elements called Silicon Objects (or simply, “objects”) and synchronous inter-object communications. As noted, we will refer herein to a core region of such a device in which an array of core objects (or “silicon objects”) is disposed. Periphery blocks are disposed in a periphery region. An array of Silicon Objects can include a single physical instance of one object type, up to many physical instances (hundreds or thousands) of heterogeneous objects arranged in any order. Each object potentially is individually programmable by the user, able to function autonomously and interfaces to every other object in an identical manner regardless of object type or position within the array. An entire array of programmed objects can function as: (a) a collection of autonomous objects, (b) autonomous object clusters (subset of the entire physical array logically working together) or (c) a single array (all objects that make up the array logically working together).

### Core Object Logic and Interface Elements

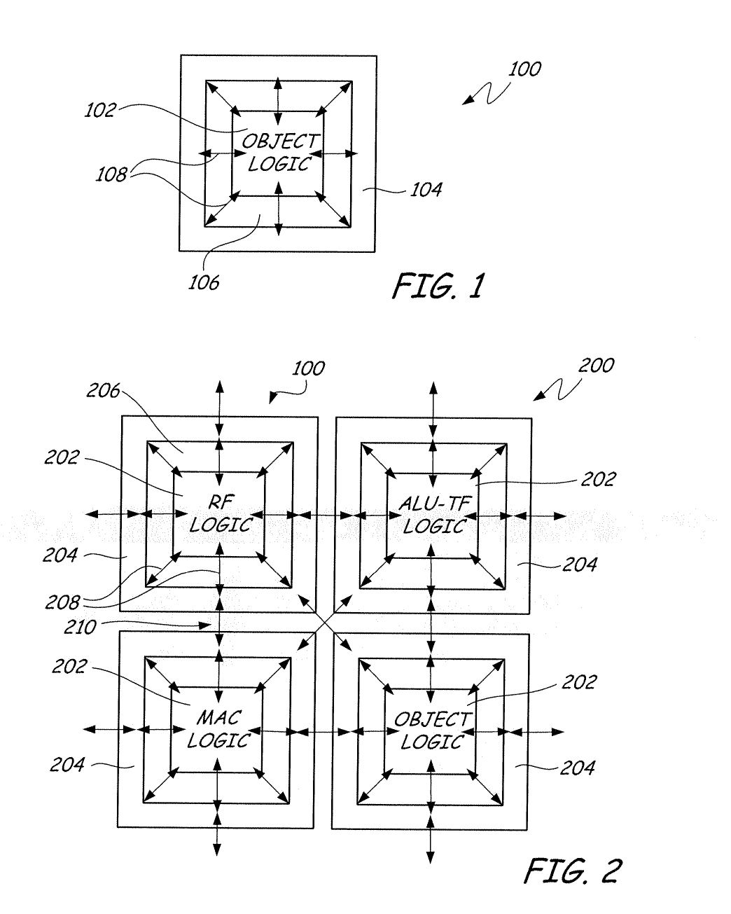

FIG. 1 is a simplified block diagram of a silicon object 100 according to one embodiment of the present invention. The silicon object 100 includes object logic 102 and a homogenous communications infrastructure (or “donut”) 104. As used here, the term “homogenous” refers to a similar or uniform communications layout pattern for each silicon object 100. The donut 104 is preferably uniformly sized and shaped to facilitate interconnections with other silicon objects 100 to form silicon object arrays. Preferably, the layout pattern for the donut 104 is identical for all donuts in the array. In one embodiment, the electrical connections between adjacent silicon objects is by abutment only. The donut 104 is arranged in a ring-like shape defining a central area 106 sized to fit the object logic 102 and to adjacent silicon objects. Signal interconnections 108 communicatively couple the donut 104 to the object logic 102.

However, it should be appreciated that the specific design or layout pattern of the “donut” region need not necessarily be identical for all core objects. Nor must it have a donut shape at all. What is required is simply that each core object design includes implementation of the common communication elements that are described herein. For example, as long as a core object provides the defined nearest neighbor and party line communication elements, so that it “cooperates” with other objects in forming the logical communications fabric, the object need not adhere to any specific physical design or layout. It is preferred to use a consistent design for the interface elements of a core object.

In the illustrated embodiment, the logical “donut” implements a homogenous communication infrastructure and physical layout, which can accept heterogeneous object logic 102 within central area 106. The term “object logic” is used broadly herein to include all manner of programmable, combinatorial or sequential logic. A few examples would include multiply and accumulate (MAC) units, arithmetic logic unit (ALU), content-addressable memory (CAM), as well as other memories, register files, and the like. Thus, object logic can include function specific object logic such as an a cyclic redundancy check (CRC) generator, an integer/real/complex multiplier, a Galois Field multiplier, or any other special function, as well as control or state-processing functions. These items are enumerated by way of illustration and not limitation. As used herein, the term “heterogeneous” is used to refer to logic that may vary in kind or nature, depending on the specific implementation.

The object logic 102 is designed to interface with the communications donut 104, which is in turn designed to interface with other silicon objects 100 in an array of silicon objects, as well as with periphery blocks adjacent to the array, as further described below. These illustrations are expanded for clarity; there is no requirement for any particular spacing or gap between the object logic and the surrounding communication infrastructure. These interfaces are not limited to data communications; other functions will be described as well.

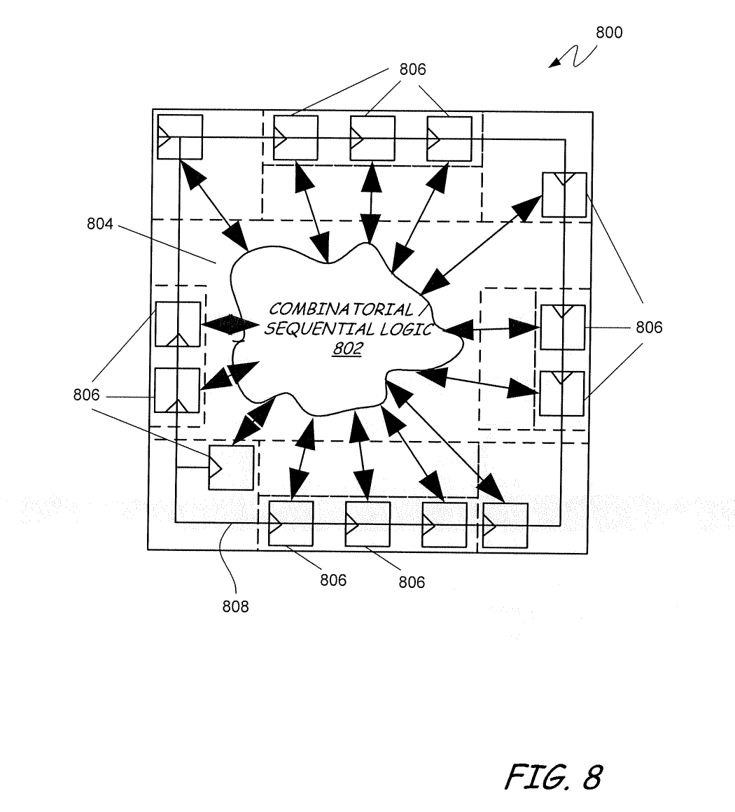

The donut 104 preferably includes a common clock bus (shown in FIG. 8), which synchronizes elements of the communications infrastructure within the donut 104. The donut 104 may be custom designed and preferably is reused by all silicon objects 100 in an array of silicon objects. By implementing the communication infrastructure in a consistent, synchronous donut 104, assembly of the array of silicon objects 100 becomes a straightforward construction. In this way, a wide variety of different implementations (FPOAs) can be easily designed to target desired applications. Since each donut 104 embodies a consistent and synchronous communications infrastructure and all communication are handled by the donut 104, timing is correct by construction among silicon objects 100 in the array, at least locally. The donut 104 confines the conventional place-and-route timing-closure issue to a manageable scope, namely timing closure and signal integrity within the object logic 102 and between the object logic 102 and the donut 104. Synchronization across multiple objects is discussed further below.

The donut 104 in this illustration physically separates the communications elements from the object logic 102, thereby making it possible to design object logic to fit the central area 106 and to interface to a standardized communications interface (the donut 104). This makes it possible to design a layout of a circuit in less time than conventional techniques, while making full use of existing process technology. In addition, the design of each silicon object 100 is done only once and the silicon object 100 can then be reused multiple times, thereby amortizing the design costs across all designs that use the particular silicon object 100.

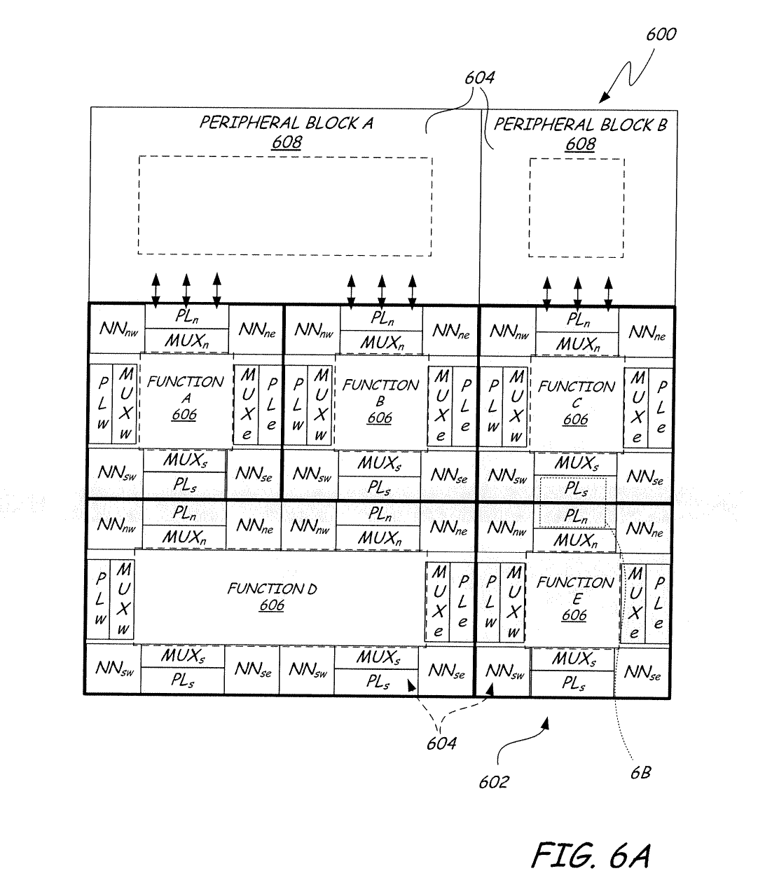

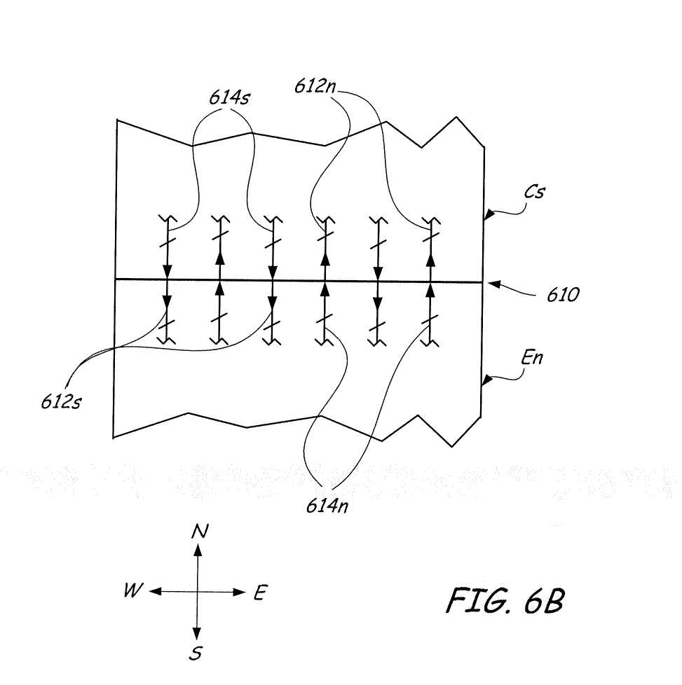

FIG. 2 is a simplified block diagram of a two-by-two array 200 of silicon objects (or “core objects”) 100. Each silicon object 100 includes object logic 202 and a homogenous communications interface 204 (donut 204). The object logic 202 is disposed within central object logic area 206 defined by the donut 204 and is communicatively coupled to the donut 204 by communication paths 208. In one embodiment, for example, communication between silicon objects 100 is achieved by abutment (as shown in FIGS. 6A and 6B). Specifically, since the communications interface 204 is standardized and is incorporated in each silicon object 100, abutment of one silicon object 100 to another results in an interconnected array 200 of silicon objects.

It should be appreciated by workers skilled in the art that the donut 204 decouples the communications interface from the logical or functional element of the silicon object. Consequently, timing can be closed or standardized for the donut 204, which is reused for each silicon object. The object logic 202 can then be adapted to interface with the donut 204, and interconnection of the entire silicon object array 200 becomes trivial.

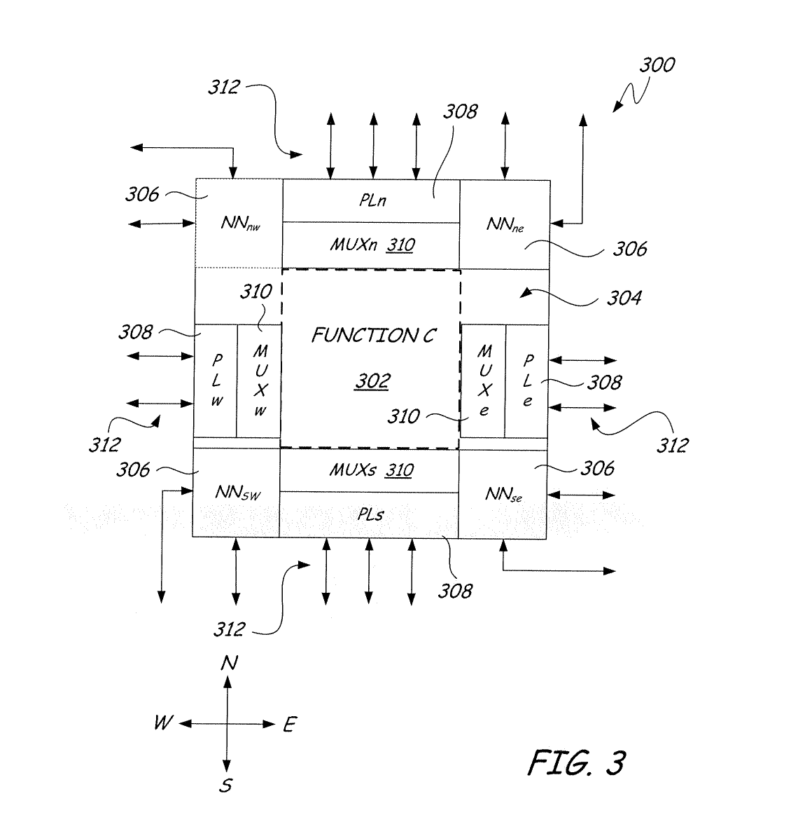

FIG. 3 is a simplified block diagram illustrating the homogenous communication infrastructure, physical layout and object logic of a silicon object 300 according to an embodiment of the present invention. The silicon object 300 includes object logic 302 and the communications donut 304. As previously discussed, the object logic 302 may include programmable processing elements or fixed function object logic.

The donut 304 includes functional communication blocks common to each silicon object 300. These structures implement inter-object communications (both among core objects and with periphery blocks). In general, inter-object communications within an array is accomplished using two, independently configurable, bus-like structures. These two structures are called Nearest Neighbors and Party Lines as mentioned above. Together the Nearest Neighbors and Party Lines define the interfaces between objects, enabling every object in the array to present itself in an identical manner to every other object. They can also be extended into the periphery blocks. Both Nearest Neighbors and Party Lines are dedicated uni-directional buses carrying data and control information. The Nearest Neighbors and Party Lines are synchronous to each other and synchronous to the objects in the array.

Nearest Neighbor communication allows a core object to communicate with any of its immediate neighbors (adjacent objects) and/or adjacent periphery blocks, without any clock delays. “Party Line” communication allows an object to communicate with objects at greater distances, i.e., remote (non-adjacent) objects, or between the core and the periphery. Party line communication requires at least one clock delay. Functionally, the interconnect framework (also called a communications fabric) comprises a configurable mesh of connections used to transfer signals and data between core objects (and periphery blocks). Any object can communicate with any other object through party line communication. In a presently preferred embodiment, at 1 GHz, PL communication can occur across four core objects in one clock cycle. In a preferred embodiment, one communication channel (PL or Nearest Neighbor) is defined as a 21-bit signal comprised of 16 register data bits (R bits), 1 valid bit (V bit), and 4 control bits (C bits). Although data bits and the valid bit typically travel together (and are sometimes referred to as VR bits), each C bit signal can travel independent of the VR bits and of the other C bits.

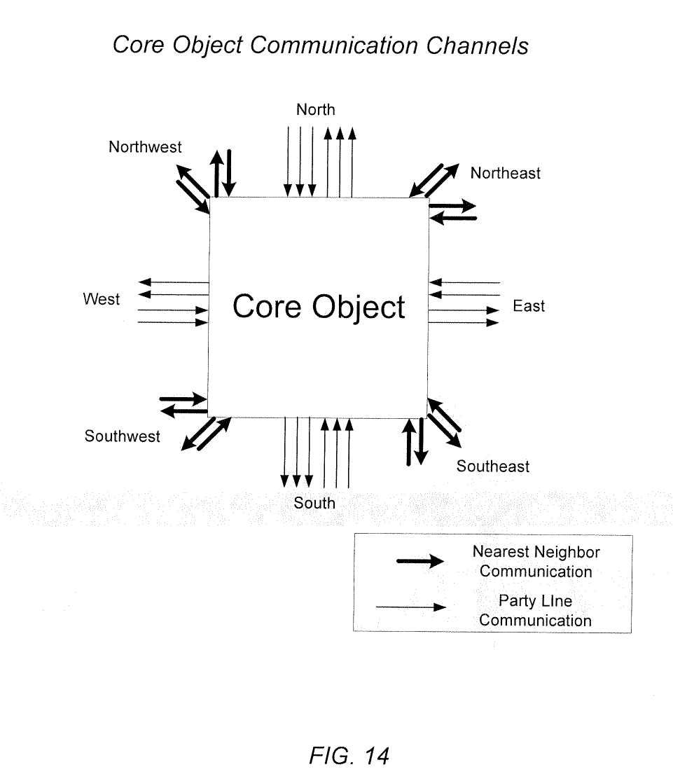

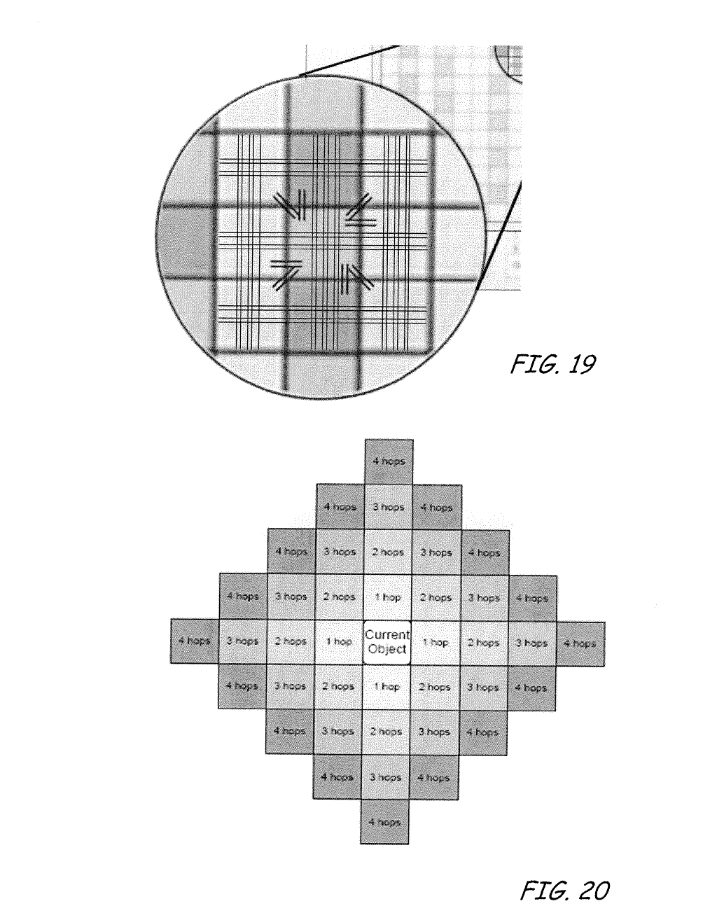

FIG. 14 is a simplified diagram illustrating a core object having 8 nearest neighbor channels and 10 full duplex party line channels. (FIG. 19 is a conceptual depiction of PL and Nearest Neighbor communication channels within the larger context of the interconnect framework.)

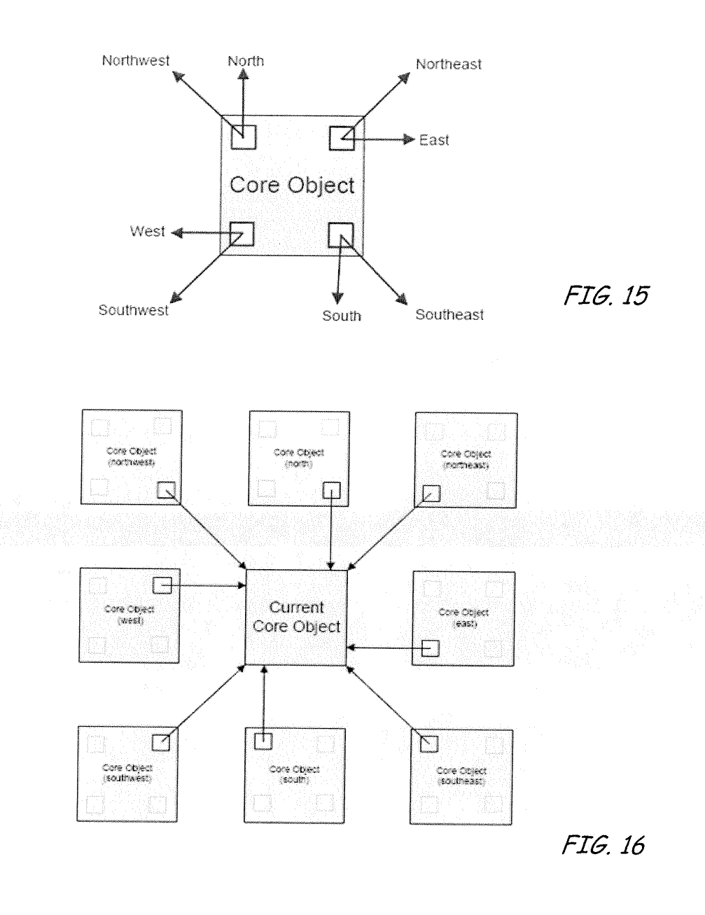

Referring now to FIG. 15, it illustrates one core object, showing four nearest neighbor (Nearest Neighbor) communication registers near the corners. Nearest Neighbor (Nearest Neighbor) communication provides a direct connection between physically adjacent core objects without any latency. In one embodiment, each core object has four Nearest Neighbor registers. Each register can be used as inputs to two adjacent core objects as shown in the figure. In this embodiment, each Nearest Neighbor register sources signals (provides input) to one laterally adjacent object and to one diagonally adjacent object; for example the paths labeled South and Southeast.

Referring back to FIG. 3, donut 304 includes nearest neighbor communication blocks 306, party line communication blocks 308 and multiplexers 310. For identification, each functional communication block is identified directionally according to north, south, east and west directions indicated by arrows 312. Thus, nearest neighbor communication block 306 in the lower left-hand corner of the silicon object 300 is labeled “NN_{sw}” for nearest neighbor (southwest).

When organized into an array, the silicon objects 300 communicate with other silicon objects through the nearest neighbor communication blocks 306 or through one or more of a plurality of “party lines”, which extend in orthogonal north, south, east and west directions, as indicated by arrows 312, which are coupled to the party line communication blocks 308. Non-adjacent silicon objects 300 communicate using “Party Lines”. Party Lines are unidirectional segmented bus structures that communicate in vertical and horizontal (Manhattan) directions in the illustrated embodiment. A bus is “segmented” in that the bus passes through at least some functional logic circuitry (e.g. object logic 302) and/or a register of the donut 304 along the way from one bus segment to the next bus segment. Each bus segment is not required to connect to adjacent silicon objects 300 in the sense of communicating with the corresponding logic core; however, depending on the specific implementation, party line segments may connect to adjacent silicon objects through the donut structure 304.

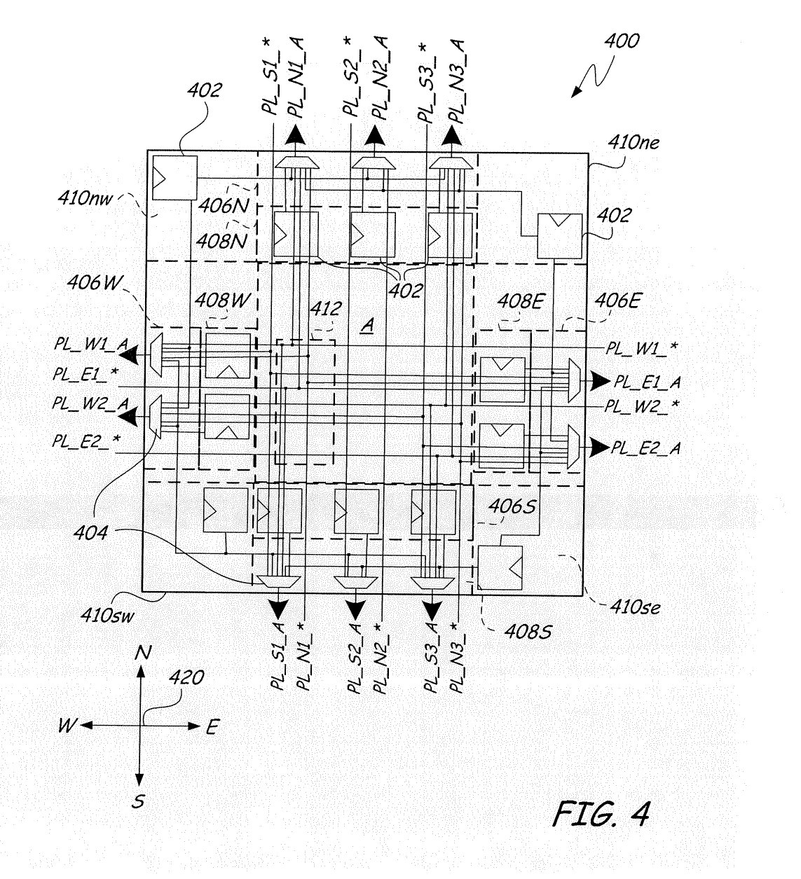

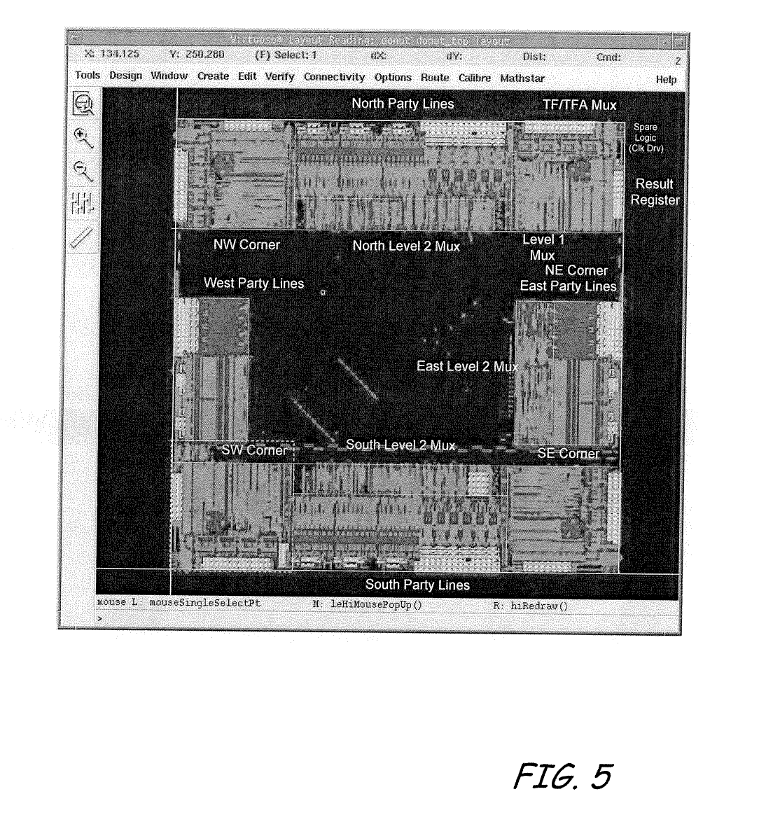

FIG. 4 is a simplified diagram of a re-configurable communication fabric underlying a homogenous communications donut 400 of a silicon object according to an embodiment of the present invention. In a preferred embodiment, each silicon object includes a communications donut 400, which couples the object logic of the silicon object to a larger array comprised of a plurality of silicon objects.

In this configuration, the communications donut 400 is comprised of a plurality of registers 402 and multiplexers 404. For the sake of clarity, the communications donut 400 is associated with silicon object “A”. Signals are labeled according to the silicon object that drives them. Signals that are driven from outside the silicon object A are suffixed with “_*” in FIG. 4. For example, in the northerly direction, the communications donut 400 receives a signal or group of signals “PL_N1_*” from outside of the silicon object A. Communications donut 400 also drives a signal, PL_N1_A to another silicon object in an array of silicon objects. In the vertical direction (north), three party lines extend northward (and are labeled with notations N1, N2 and N3); and three party lines extend southward (S1, S2, and S3). Two party lines extend westward and eastward (W1 and W2, and E1 and E2, respectively).

In general, communication proceeds synchronously. Communication buses (party line or nearest neighbor) are driven by registers. A receiving silicon object loads a received signal into a register and reads the control signals and/or data in the next clock cycle. The nearest neighbor channel connects through the nearest neighbor block from a nearest neighbor block of an adjacent silicon object, and the nearest neighbor can connect to the processing by the object logic of the receiving silicon object directly. Alternatively, data received through the nearest neighbor block can be loaded into a nearest neighbor register and redirected onto one or more party lines in the next clock cycle. By contrast, party line channels connect to a landing register of a receiving object prior to any processing object logic. The party line channel provides the communication among objects with a deterministic latency.

In one embodiment, the donut 400 of the silicon object has ten party line inputs (PL_*_*), ten party line outputs (PL_*_A), party line launch circuits 406, multiplexers 408, party line landing circuits 412, and a function-specific logic block (“core”), which is labeled as “A”. In one embodiment, party line inputs and outputs are each 21-bits wide and include control bits C[3:0], data bits R[15:0] and valid bit V.

Values on party line inputs can be captured, for example, by a landing register 412 (shown in phantom) for use by a logic block or for synchronizing the value with a local clock signal and transmitting the value back onto the same or a different party line through the party line launch circuit 406. The landing register 412 is shown in phantom to indicate that specific placement of the landing register may vary provided that inputs to the landing register mate with input pins in the expected location on a periphery of the donut structure 400.

In one embodiment, the donut 400 includes multiplexers 408 and party line launch circuitry 406, landing circuitry 412 (shown in phantom), as well as nearest neighbor communication blocks 410. In one embodiment, landing circuitry may be omitted from the donut 400. In another embodiment, landing circuitry 412 is omitted from the donut 400 but is included in the logic block as needed. Alternatively, the landing registers may be included in the donut 400.

The landing circuitry 412 may include one or more registers adapted to store data received from one or more of the party lines. Each register of the landing circuitry can capture values from one of two party lines or a result output from the logic block. Each landing registers in the landing circuitry 412 has outputs that are coupled to logic block A and to inputs of party line launch circuit 406. Alternatively, the landing registers may redirect data to a nearest neighbor block 410.

The communications donut 400 is configured to transmit data onto party lines via party line blocks 406 or to transmit data to adjacent silicon objects in an array via nearest neighbor blocks 410. The party line launch circuit 406 can be configured to selectively “pass” a value received from the previous silicon object on one party line to the next segment of the party line on an output, “turn” the value from the previous silicon object to a different party line, or replace the value with a new value from logic block A or landing circuit 412, which can then be transmitted to one of the party line outputs. In the pass through case, the party lines effectively pass through the object without becoming involved with that object. In other words, the object logic neither receives nor transmits data on those party lines.

For example, a southward traveling data signal is received from a northerly direction by the donut 400 on input line PL_S1_*. The object logic A may be configured with a landing circuit 412 for receiving the data from the signal, which can be stored in one or more registers of the landing circuit 412. The object logic A, on the next clock cycle, can read the data out from the registers of the landing circuit 412, process the data, and send the processed data onto outgoing party line PL_W1_A, PL_E1_A, PL_S1_A, and/or PL_N1_A (or onto any other outgoing party line). In another embodiment, the party line circuit 406 may be configured to pass the data signals received from a previous silicon object on a party line segment to a next silicon object on a next party line segment, directly, and in any out-going party line direction (e.g. North, South, East or West).

In one embodiment, data received from an adjacent silicon object may be received either over a party line connection or via a nearest neighbor block 410. Data received in a nearest neighbor block 410 may be passed directly to object logic A for processing, or may be clocked into a landing register, and sent out to another silicon object either via a nearest neighbor connection or over party line connections, as desired.

Data processed by the object logic A can be written to registers 408 (north, south, east or west) and driven onto a party line by the party line circuit 406. Thus, at each silicon object, data can be received by the object logic or passed on by the donut 400, depending on control signals associated with the data signal or based on the donut configuration.

Within an array of silicon objects according to an embodiment of the present invention, silicon objects are connected together through their respective communications donuts 400 by a plurality of party lines running in orthogonal north, south, east and west directions as indicated by arrows 420. As previously indicated, party lines are unidirectional segmented buses that communicate in vertical and horizontal (Manhattan) directions. A bus is “segmented” in that the bus passes through at least some combinational logic and/or a register 402 from one bus segment to the next bus segment. Each bus segment is not required to connect to (to land in a landing register of) proximal silicon objects. For example, in one embodiment, a bus segment may connect only to every other silicon object through which it passes. A more detailed discussion of the unidirectional segmented bus architecture is provided in U.S. patent application Ser. No. 10/337,494, filed Jan. 7, 2003 and entitled “SILICON OBJECT ARRAY WITH UNIDIRECTIONAL SEGMENTED BUS ARCHITECTURE”, which is incorporated herein by reference in its entirety. In an alternative embodiment, Party Lines can “pass through” objects in a number of ways including straight, 45 deg right turn, 90 deg right turn, 135 deg right turn, 135 deg left turn, 90 deg left turn and 45 deg left turn.

### Nearest Neighbor Communications

As the name implies, these communications transfer signals between neighboring, i.e., immediately adjacent objects in an array. (They can also connect to adjacent periphery blocks.) In a regular rectilinear array, for example, each object (except along the edges of the array) will have eight neighbor objects (See FIG. 16.) “Nearest Neighbor” communication allows a core object to communicate with any of its immediate neighbors without any clock delays. All eight neighbor objects surrounding a “current object” provide source registers as working registers for the internal functions of the current object core logic. Specifically, those are the Nearest Neighbor registers, of which there are four in each object donut region, conceptually in the corners. See FIG. 4.

Theoretically, where objects in an array have a rectilinear shape, for example, the intersection between two diagonally-adjacent objects is merely a point. As a practical matter, no circuitry can be implemented exactly at that point, but direct communication with no latency between two diagonally-adjacent objects is desired. To implement that functionality, each Nearest Neighbor structure (or “block” as it was called with reference to FIG. 4) includes more than a local result register; it also includes connection paths or “wires” that “cut the corner” to implement a diagonal Nearest Neighbor connection between two adjacent objects, as explained further shortly. Each object thus has responsibility for implementing certain Nearest Neighbor connections where it merely acts as a conduit; i.e., it is neither a source nor consumer of the signals that traverse those connections and it does not alter them.

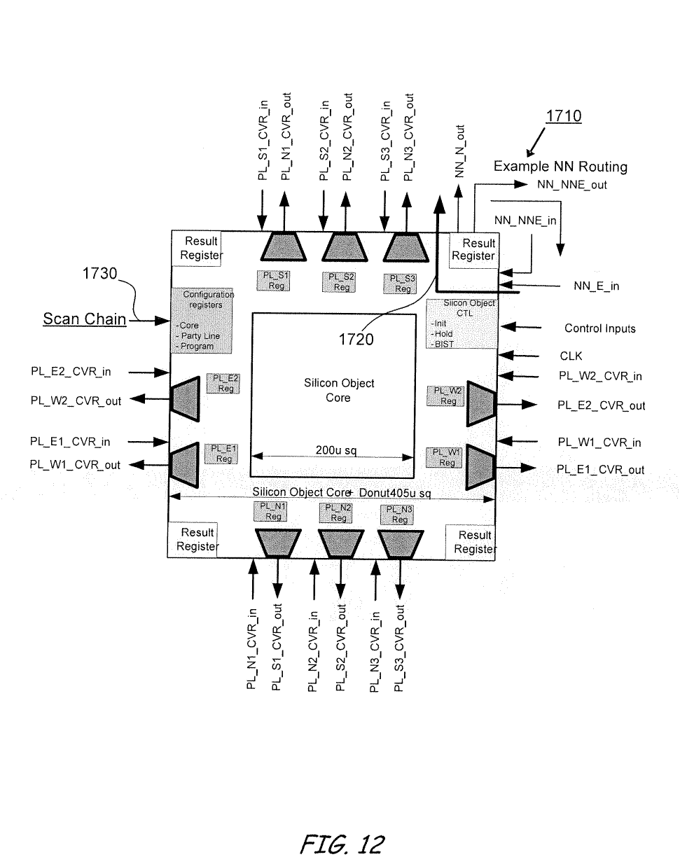

FIG. 12 also illustrates an object and various donut structures. In each corner, a result register is shown as explained for Nearest Neighbor communications. In the upper-right corner region, see “Example Nearest Neighbor Routing” 1710. As before, a path 1720, shown as a heavy line for identification, implements a diagonal output connection to the north from the neighbor object to the east (right), i.e., the Northwest output for that object. Note that this connection does not involve the result register. These connections preferably are physically arranged in each object donut region so that the necessary electrical contacts are established simply by abutment of neighboring objects. By using a consistent arrangement of such communication structures in the donut or periphery of every object, regardless of its core function, mere placement of the objects in abutment in the array automatically creates the communication fabric.

It is important to distinguish the local Nearest Neighbor registers (used for input and output) from the Nearest Neighbor registers of the adjacent core objects (used for input only). The following convention can used to describe their direction: Each of the four local Nearest Neighbor registers is defined by its two output directions: NNW (North/Northwest), ENE (East/Northeast), SSE (South/Southeast), WSW (West/Southwest). These are illustrated in FIG. 20. Each of the eight neighboring Nearest Neighbor registers, used for input only, is defined (relative to the current object) by its direction: NW, N, NE, E, SE, S, SW, W. These eight inputs are illustrated in FIG. 16.

Referring again to FIG. 15, the diagonal outputs, one from each Nearest Neighbor result register to a diagonally-adjacent object, each depend on the passive assistance of a third object (not shown here) to route signals to the diagonally-adjacent destination.

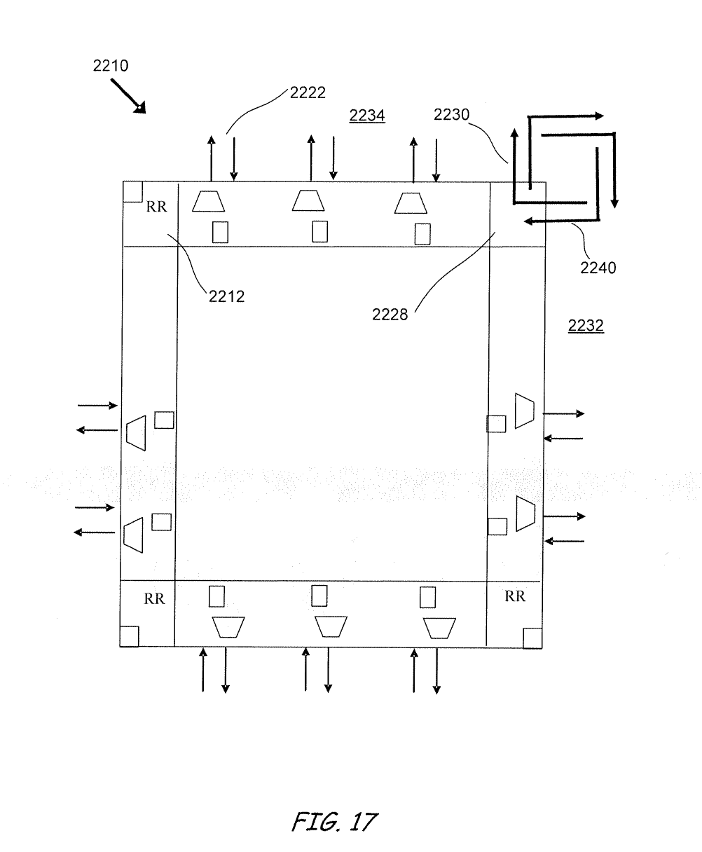

FIG. 17 illustrates an object 2210 in simplified form, showing some of the donut structures and Party Line channels, e.g. 2222. In each corner of the object, an Nearest Neighbor structure, e.g., 2212, includes a corresponding result register (“RR”). In the upper-right corner 2228, four Nearest Neighbor paths are shown. One of them, path 2230, passes through the current object 2210, so as to implement a diagonal connection between the east neighbor object 2232 and the north neighbor object 2234. Thus object 2210 implements the Northwest output from object 2232 (Norwest corner) via path 2230. Similarly, it can be seen that a path 2240 provided in object 2232 implements the Southeast diagonal output for an object (not shown) to the north of 2232. The remaining two paths (not numbered) in the same neighborhood should now be understood as illustrating Nearest Neighbor diagonal connections.

### Summary of Source and Result Registers

Core objects use PL launch/land registers and Nearest Neighbor registers as working registers for their internal functions. Inputs to the internal functions can be acquired from any of 19 “Source Registers”. These include:
4 local Nearest Neighbor registers
5 PL land registers
8 adjacent Nearest Neighbor registers (located in the eight adjacent core objects)
2 local constant registers (which are programmed during initialization)′these are sometimes referred to as K registers

Results from these internal functions can be saved to a set of fewer registers, called “Result Registers”. These include:
4 local Nearest Neighbor registers
5 PL launch registers

### Periphery Region and Periphery Blocks

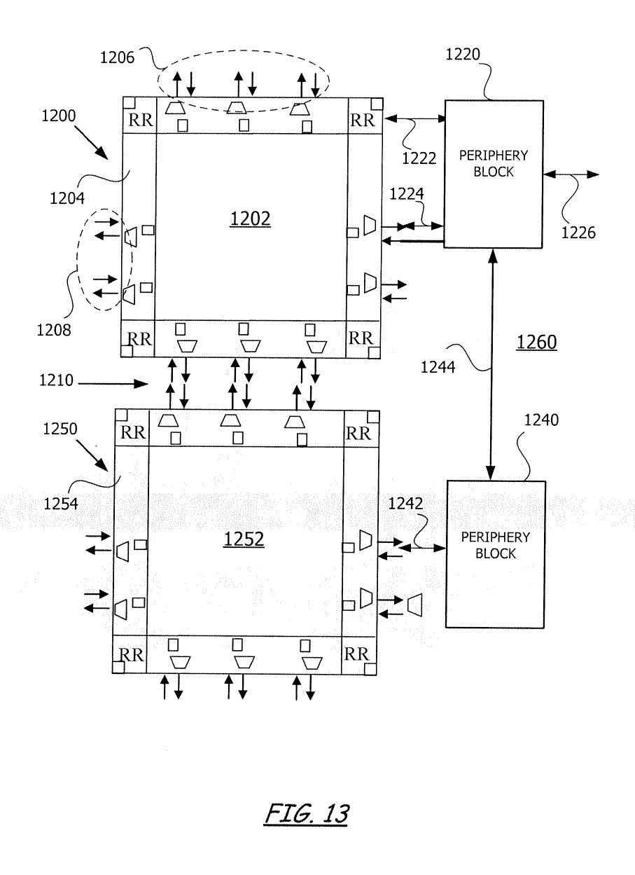

FIG. 13 is a simplified block diagram illustrating two adjacent core objects and two periphery blocks. In FIG. 13, a first core object 1200 is positioned adjacent a second core object 1250. Although the two core objects are shown as spaced apart for purposes of illustration, they are preferably abutting one another in practice, for example, along the edges where party line connections are shown generally at 1210. Specifically, this illustrates three north-south party line interconnections. The core object 1200 comprises a logic circuitry in the region 1202 and interface elements in region 1204. While the interface region 1204 is shown generally surrounding the logic circuitry 1202 in a donut configuration, this is only one example. The interface elements can be arranged in any convenient manner relative to the logic circuitry as long as the interface region implements the necessary interface elements, as described elsewhere, for interconnection to other core objects or periphery blocks.

Referring again to FIG. 13, a first periphery block 1220 is shown disposed within a periphery region 1260. The periphery block 1220 in this example implements a “nearest neighbor” connection 1222 to the core object 1200. Periphery block 1220 also implements a “party line” type connection 1224 to the core object 1200 (donut 1204). Periphery blocks can connect to core objects using either or both of these types of connections. Some periphery blocks may not connect directly to the core objects at all; rather, they may merely work cooperatively with other periphery blocks. In this illustration, a second periphery block 1240 is shown, coupled to the core object 1200 by a party line connection 1242. Periphery block 1240 is also coupled to periphery block 1220 via a communication line 1244. The communication line 1244 between two periphery blocks need not be synchronous to the core objects. Finally, periphery block 1220 shows an external connection 1226 for communication of signals outside the chip.

### Timing and Synchronization

In one embodiment of the present invention, a data path length may be constrained through software to ensure timing closure. A data path length refers to a length of a string of segments over which data may pass without being registered. A data signal may be passed from one silicon object to the next in an array without being clocked into a data register. The data path length is the maximum number of party line segments over which the data may be passed without violating a set-up time of a receiving silicon object. Specifically, if a data path length would be too long, such that the clock skew for such a distance would result in timing violations with respect to data being clocked into a landing register, the data path lengths can be constrained to avoid such set-up time violations. This makes it possible to make timing adjustments for data path lengths without altering the clock speed for the entire chip.

To illustrate, FIG. 20 shows a number of “hops” or bus segments from a current object to various surrounding objects using Party Line communications. Because a Party Line channel in a presently preferred embodiment conveys data only orthogonally, a diagonal transfer requires two hops, e.g., “up and over”. However, an alternative embodiment could implement a 45-degree (or 135-degree) “turn” option for a party line channel.

In terms of synchronization, if a maximum number of party line segments is say, four hops, without violating a receiving object's set-up time, then a constraint may be placed on the data path length requiring a data signal to be clocked into a landing register and relaunched by at least one silicon object in each four segments. During synthesis of the circuit layout, the routing tools can easily limit the data path lengths to this predetermined integer “hop distance”. Specifically, design rules can be used to impose a constraint on party line data transmissions such that data transmitted over a party line must “land” and be clocked through a register or latched every x-number of party line segments before being launched again on the party line. This ensures adequate setup and hold times before the next clock cycle. The hop distance is determined as a function of the frequency of the common clock signal.

In general, communication between silicon objects throughout the array of silicon objects proceeds synchronously through the communications donut 400. Channels are driven directly by registers 402. A receiving silicon donut 400 reads control signals and/or data from received signals in the next clock cycle. Channels can be classified to nearest neighbor (Nearest Neighbor) and party line (PL). The fundamental difference between the two types is the cycle timing. Nearest neighbor channels connect to the processing logic (object logic) of the receiving silicon object directly. Consequently, data generated by the originating silicon object is processed in the subsequent cycle by the receiving silicon object. Each silicon object can access both control and data values from each of its eight nearest neighbors via the Nearest Neighbor channels. Party line channels connect to the landing registers of the receiving object prior to any process logic. Since data and control signals received over the party line are clocked into the landing register on one clock cycle, and are read out of the landing register by the object logic on the next clock cycle, the party line channel provides communications among all objects with a deterministic latency.

By utilizing a homogenous network, the donut 400 can be standardized for all objects in the array, including peripheral devices. The donut 400 is custom designed and re-used by all objects. In one embodiment, the largest silicon object is a single cycle multiply-and-accumulate (MAC) unit, so the basic dimension of the donut 400 was selected to be the minimum area required to contain the custom designed logic of the multiplier by the donut 400. If the logic for a particular object type is larger than the object logic area of the donut 400, the logic can extend to two object logic areas.

FIG. 6A illustrates a simplified block diagram of an array 600 of silicon objects 602 according to an embodiment of the present invention. Each silicon object 602 includes a homogenous communications interface or donut 604 and object logic 606, which may be programmable or fixed. In this embodiment, function D object logic 606 is two donuts 604 wide. Since the donuts are synchronous and homogenous, the intermediate section including the east and west multiplexers and the east and west party line blocks can be removed, thereby joining two adjacent donuts 604 into a single larger ring in order to accommodate the larger logic function.

Since the donut 604 preferably is constructed hierarchically and symmetrically to the vertical axis and the horizontal axis, the donut 604 can be modified trivially in this manner to adapt to the new multi-unit object. Additionally, peripherals (indicated by peripheral blocks A and B labeled with reference numeral 608), such as external memory controllers, Built-in-self-test (bist) controllers, and the like, can be treated as a multi-unit object with an identical interface. (Examples of peripheral objects that employ two sets of communication signals (Party Lines) for interface to the core objects are given below.) Because of this conformity, the entire array is constructed by abutment automatically in physical design. Element 6B in phantom is shown in a simplified view in FIG. 6B.

FIG. 6B illustrates a simplified, conceptual block diagram of an abutment between adjacent donuts 602 in a layout pattern of the array 600 of FIG. 6A. In particular, party line south block (Cs) associated with a party line block of Function C (element 606 in FIG. 6A) is configured with input lines 612n and output lines 614s, which are arranged in the layout pattern to extend to the periphery of the donut. Each donut of each silicon object in the array has the same configuration, layout pattern, and functional elements. In other words, the donuts are homogenous and identical. Additionally, the design layout of the output pins 614s extend to the periphery of the donut at the same horizontal position (in an x-direction along a peripheral edge of the donut) and at the same layer of the donut architecture as corresponding pins on adjacent donuts in the layout pattern. This allows for two adjacent donuts to be electrically coupled by physical abutment (e.g. contact along a peripheral edge. Specifically, when the donuts are aligned and positioned such that they abut one another, output pins 614s associated with party line block Cs electrically couple to input pins 612s of party line block En associated with function E (element 606 in FIG. 6A). In this manner and along all peripheral edges of the donut (and even diagonally through the nearest neighbor corner blocks of each donut), the donut layout is arranged to facilitate coupling by abutment between adjacent donuts.

It should be understood that the input and output lines 614 and 612, respectively, need not be fabricated on the same layers, provided the output pins mate with the corresponding input pins of the next silicon object in the array. The design layout thus provides a means by which a net is established from one donut to the next in the layout. Additionally, it should be understood that FIG. 6B is conceptual and not drawn to scale. The abutment 610 is a physical line of contact between two adjacent silicon objects in a layout pattern along a peripheral edge of a donut.

Additionally, it should be understood by workers skilled in the art that the electrical connections established by such abutments may include clock signals, power and ground connections, signal routing and so on. Different electrical connections may be established through different layers and at different horizontal locations as desired, according to the homogenous layout pattern of the donut. The donut may be reused in multiple application, or may be redesigned as needed. In general, one of the advantages of the donut is its reusability. Another is the ease with which the layout design can be completed with the interconnections made automatically.

In general, the standardized, homogenous communications donut of the present invention makes it possible to interconnect an array of silicon objects trivially. The wiring input and output pins are fabricated to precisely match corresponding output and input pins of adjacent donuts in all directions. The layout of signal lines 612 and 614 automatically align so that corresponding signal wires automatically connect to one another, thereby connecting one silicon object to the next in the array. When the silicon objects are placed adjacent to one another in the layout pattern, no additional routing is required between silicon objects.

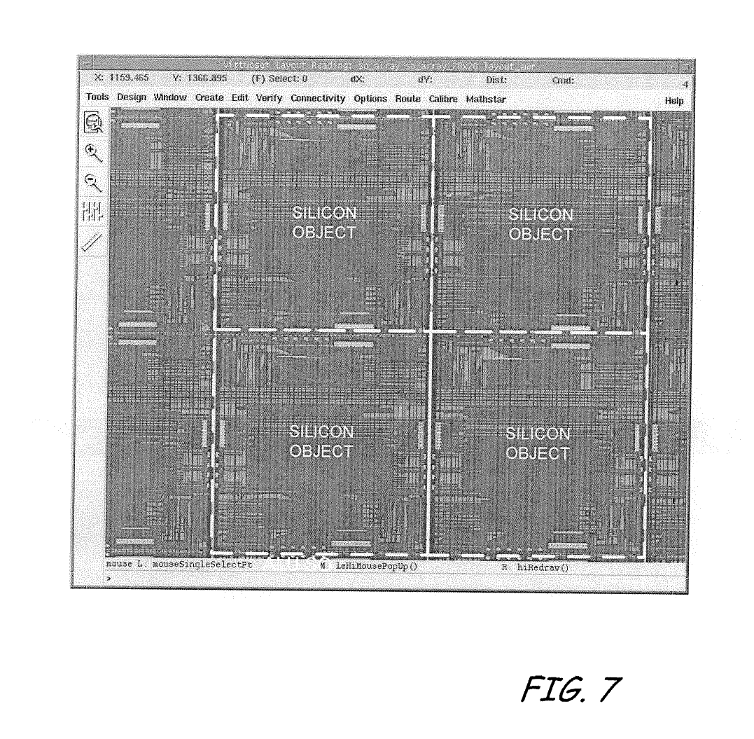

FIG. 7 is a screen shot of a layout of an array of silicon objects coupled by abutment in a window of the computer program called Virtuoso® according to an embodiment of the present invention. The outline of each silicon object is highlighted with a phantom line to illustrate the abutments, and each silicon object is shown in phantom to indicate the general location of the functional logic within the layout.

FIG. 8 is a simplified block diagram of a silicon object 800 according to an embodiment of the present invention. The silicon object 800 includes combinatorial and or sequential logic 802 (object logic 802) and a homogenous communications interface or donut 804. The donut 804 is provided with a plurality of registers 806 adapted to store data read from one or more party lines or nearest neighbor connections. A common clock bus 808 is provided within the donut 804 to synchronize the registers 806. The clock bus 808 synchronizes all the registers within the donut 804, such that data received by the donut 804 for processing is synchronized to the clock signal before being read into the object logic 802. If data is received from a nearest neighbor through a nearest neighbor block, it may be trusted as being synchronous because clock skew between adjacent silicon objects is minimal (meaning it can be neglected for the purpose of signal and data integrity).

In general, the donut 804 includes a buffer in each corner of the donut structure, to which the common clock bus 808 is coupled. During design, a design tool in conjunction with a mapper couples one of the buffers of a donut 804 of silicon object 800 to a clock spine of the integrated circuit layout. Each donut 804 within an array of silicon objects 800 receives the clock signal via a buffer either directly from the clock spine or from a wire segment coupling the buffer to an adjacent silicon object. In general, a rib segment may extend from silicon object to silicon object in an array, coupling a clock bus 808 of each silicon object to the master clock spine.

Since all communication between objects is handled by the donut 804 which is fully synchronous (because of the common clock bus 808), timing is correct by construction among objects, and physical effects can be readily accounted for. The only requirement is that timing closure and signal integrity must be correct within the object logic 802 and between the object logic 802 and the donut 804.

To continue the same approach, the interface of the donut to the internal logic of each block is characterized and standardized. Thus, the integration of the computational logic 802 is easily integrated by enforcing the scope of timing closure and logical design into a relatively insignificant area.

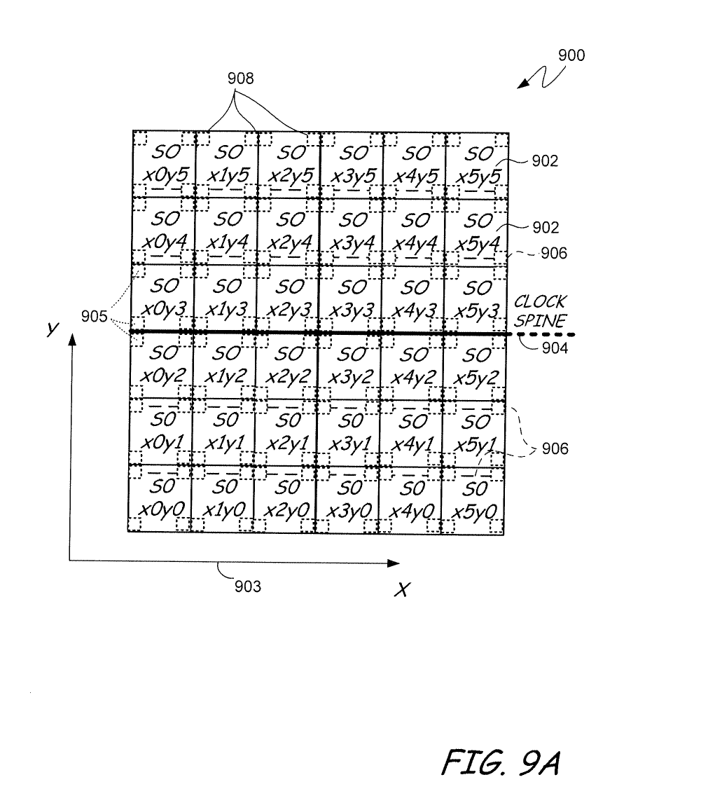

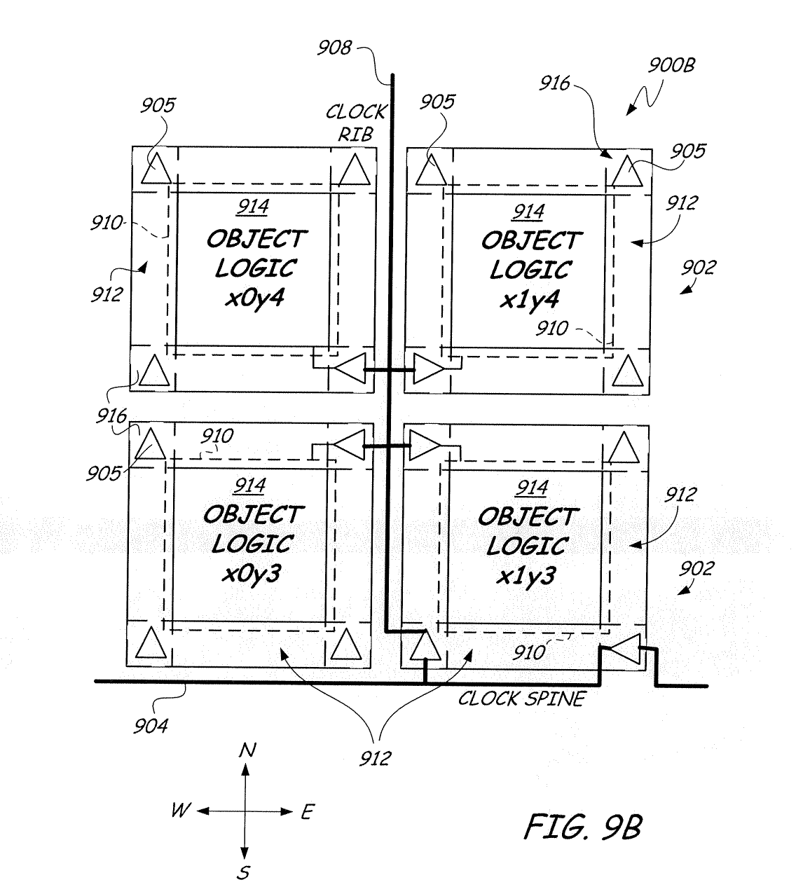

FIG. 9A illustrates a simplified array 900 of silicon objects 902, which are coupled by abutment. In general, the homogenous donut architecture renders clock skew due to propagation delays between core objects into completely predictable and trivial calculations. In particular, since the array 900 of silicon objects 902 is arranged in a symmetric matrix, and since each silicon object has a consistent size and shape, a timing delay associated with the clock signal as it is received at each silicon object is completely predictable. Earlier, with reference to FIG. 8, we showed how each individual core object design includes clock distribution to the core logic and the donut structures. Each object design also includes internal power distribution. In the following paragraphs, we describe clock distribution across the array, and how each object provides resources, e.g., clock buffers, to support that global signal distribution. Such local resources, further described below, support not only clock distribution and synchronization, but other global control signals such as HOLD, INITIALIZE and BIST signals.

For example, silicon object x0y3 is directly coupled to the clock spine 904 via a clock buffer 905 in a corner of the silicon object, and therefore has a clock signal that is approximately the same as a clock signal of the clock spine 904. Other silicon objects 902 may be coupled to the clock spine 904 directly through a buffer 905, or may receive a clock signal through abutment to another silicon object 902.

If the clock signal is received via abutment, a buffer 905 in one silicon object is coupled to a buffer in the adjacent silicon object 902 via a wire segment (not shown). For each silicon object 902 that is coupled directly to the clock spine 904, the clock signal is assumed to be correct. For silicon objects 902 coupled to the clock spine 904 indirectly through an adjacent silicon object 902, the clock skew is predictable, and timing can be readily adjusted with a simple algorithm. Specifically, the skew from x0y0 to x0y1 is the same as the skew from x0y2 to x0y3 and so on. Since each donut is identical, the skew is exactly uniform across the array of objects. Thus, the donut 902 renders clock skew correctable by a trivial calculation.

The homogenous and synchronous donut architecture of the present invention provides the opportunity to employ a scalable symmetric clock tree, such as fish-bone or H-tree for the design. Specifically, by constructing the clock tree from tracks in the layout pattern and clock buffers provided in the rectilinear, homogenous and synchronous donut structures of the array, a clock tree can be scripted readily, and is extendable throughout the array as needed. Since the homogenous and synchronous donut structure has the same dimensions for each instance throughout the layout pattern, clock skew between blocks is predictable, and the overall skew performance is then satisfied. Ones can be automatically generating using a simple script. The overall skew performance is then satisfied.

Ribs 908 are coupled to clock spine 904. In one embodiment, the ribs 908 couple to the clock spine 904 through the buffer 905 of a silicon object 902. The ribs 908 with the clock spine 904 represent an scalable symmetric clock tree. The clock may be implemented in an H-tree or fishbone-type clock tree arrangement. Mesh 906 illustrates a voltage wire extending across the array 900. Because the donut 902 is symmetric and because all registers are located in a periphery of the donut, the clock loading is balanced. The common clock bus can be part of the donut, and the clock tree can distribute clock signals to the clock ring bus architecture of the various donuts 902 (as is shown in greater detail in FIG. 9B).

FIG. 9B is a simplified expanded block diagram of the array of a two-by-two portion 900B of the array of FIG. 9A. The portion 900B is comprised of four silicon objects 902 (x0y3, x0y4, x1y3, and x1y4). Each silicon object is comprised of a communications donut 912 and an object logic area 914. Each communications donut 912, in addition to communications elements (shown, for example, in FIGS. 3, 4, 5, 6A, and 8-11), contains a clock bus 910 (also shown in FIG. 8). Generally, each corner of each silicon object 902 has a cell block 916 (not drawn to scale in order to show the clock connections). Each cell block 916 can include, for example, clock buffers 905, logic inverters and flip-flops (not shown).

These clock buffers 905 make it possible to construct a fishbone clock tree. For example, a southeast clock buffer 905 of silicon object 902 (identified as x1y3) couples to the clock spine 904 to route clock signals along the clock spine 904 in an East-West layout. Since the locations of the clock buffers 905 are deterministic (meaning the layout pattern is identical for all donut structures 912 in the array, it is possible to use the donut structures 912 to generate a scalable clock tree. Specifically, clock tracks (such as clock spine 904) can be reserved in the layout pattern of the donut structure 912. The connections from the clock buffers 905 to the clock tracks can be scripted during layout to generate the clock tree. As shown, a second buffer 905 in the southwest corner of the silicon object 902 (identified as x1y3) is coupled to the East-West clock spine 904 and is adapted to route the clock signal onto North-South clock rib 908.

In the embodiment shown, all four silicon objects 902 derive their clock signals from the North-South clock rib 908, which is coupled through the Northeast, southeast, northwest, and southwest corners of silicon objects x0y3, x0y4, x1y3, and x1y4, respectively. Here, clock skew between the four silicon objects is negligible. However, since the size of the silicon objects 902 is deterministic, clock skew is predictable.

By building the clock tree through the clock buffers 905 provided in each corner of each silicon object 902, an extra processing step is not necessary to place and route the clock tree. Similarly, in the same cell block 916, it is possible to script the generation of a global reset tree using the flip flops (not shown). Unused cells can be tied down to reduce power and noise. As noted above, these local resources provided in each core object also support a variety of global control signals.

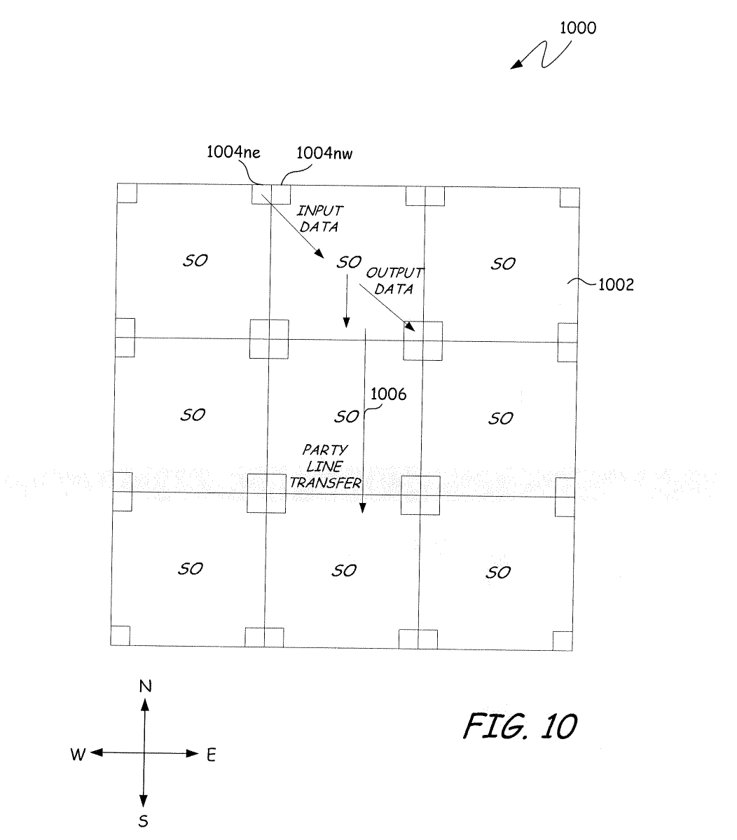

FIG. 10 is a simplified block diagram of a silicon object array 1000 according to an embodiment of the present invention. Each silicon object 1002 is provided with a nearest neighbor communication block 1004 at each corner (NW, NE, SW, and SE) of the object 1002. As shown, data driven by nearest neighbor communication block 1004ne can be input directly to the object logic of the neighboring silicon object on the next clock cycle, passing through the nearest neighbor block 1004nw without clocking into a register. The received data can be processed and then sent over the party line 1008, for example, to a non-adjacent silicon object, where it is received in a register on the next clock cycle. Alternatively, the received data can be forwarded to any of the eight adjacent silicon objects via a nearest neighbor communication block 1004. Alternatively, data may be received by nearest neighbor block 1004nw from nearest neighbor block 1004ne and clocked into a register, before the data is launched onto a party line or transmitted to another nearest neighbor in an array.

### Power Distribution and Control

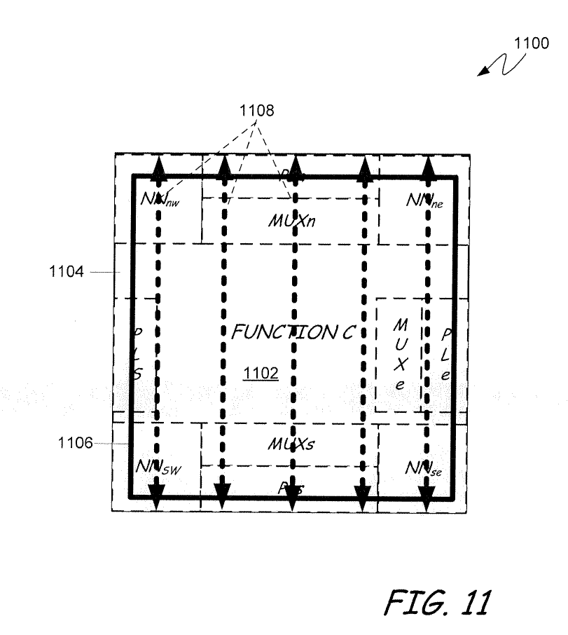

FIG. 11 is a simplified block diagram of a silicon object 1100 according to an embodiment of the present invention. The silicon object 1100 includes object logic 1102 and a homogenous communications donut 1104. A common clock (or clock ring) 1106 is provided within the donut 1104 to synchronize the registers of the communications donut 1104.

Because of the symmetric nature and because launching registers are located in the periphery of each silicon object 1100 as part of the donut structure 1104, the clock loading is balanced across the silicon object 1100. The clock bus or ring 1106 can be part of the donut 1104, and the clock tree (of the silicon array) delivers a clock signal to the clock bus 1106 of each silicon object 1100, either directly or indirectly. Because of the small size of the silicon object 1100, the clock skew within a silicon object 1100 is practically insignificant.

Finally, a conductive power bus is shown, which overlays the silicon object 1100, preferably at a top metal layer, such as metal layer 8, for an integrated circuit having eight routing layers. The conductive power bus 1108 may extend over the peripheries of the silicon object 1100 at locations corresponding to a power pin fabricated to a periphery of the silicon object 1100 to deliver power to the donut 1104, which in turn delivers power to the object logic 1102. The conductive power bus 1108 are routed in a grid across the area of each silicon object at regular spacing intervals. Individual components within the silicon object can be supplied with power by routing power and ground straps to these power buses. With such power grids, the overall power mesh may then be connected by abutment of each of the silicon objects 1100 in an array. Since peripheries share the same rectilinear donut 1104 or donut-like interface (having a homogenous layout), the power bus 1108 may extend over the peripheries to power pins of the donut 1104, which can interconnect on adjacent silicon objects.

The power supply arrangement preferably enables object level power control. Each object within the array preferably can be turned on or off. In the “on” state, the object is functioning, meaning the core logic is performing some operation itself, and the object is also serving the rest of the array with communication such as the Party Lines or the sharing of the nearest neighbors as described. Every object has some responsibilities to the rest of the array, main in terms of communications, but also power, scan chain, other functions such as the distribution of global control signals discussed above. Individual objects can selectively be turned off when the specific function in its core is not required, but even in the “off” state the object still provides its array level functions. Accordingly, power remains on in the donut region. Put another way, services that a given object performs for the rest of the array cannot be turned on or off. Control of power to the core logic is implemented in the object donut region, for example responsive to a configuration register loaded by scan chain data.

The power grid 1108 may readily be tapped by one or more silicon objects 1100, and power can then be shared with other silicon objects in an array via the donut 1104. Additionally, if the power grid 1108 is laid out on metal layer 8, the silicon objects 1100 and the layout simplification provided by the donut architecture and associated methodology can readily be applied to flip-chip technologies, with no adjustment for power being necessary.

With the standardization of the donut and the clock tree structure, the donut may be designed using custom techniques to minimize area and maximize performance. Though the cost and time of custom techniques is more expensive than standard application specific integrated circuit design, the expense is greatly amortized due to its re-usability. Similar to the standard cells which are custom-designed, the basic blocks may also be custom designed for maximum performance and minimal area usage. The synthesis process may then be used, similar to the same process as in an application specific integrated circuit.

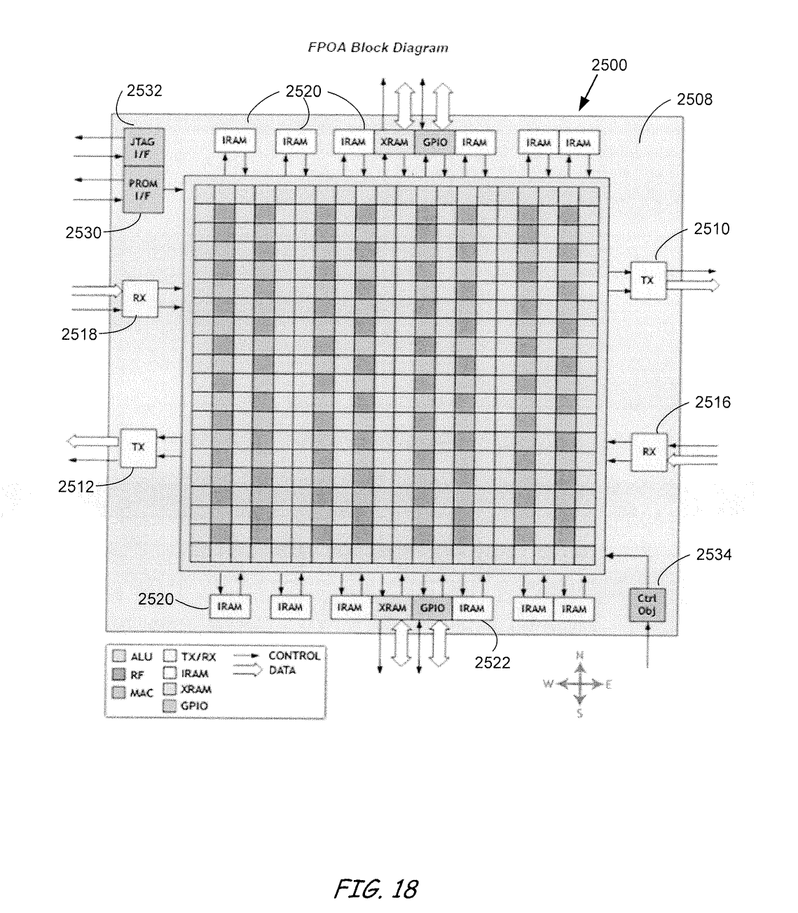

Referring again to FIG. 12, a simplified block diagram of an individual silicon object illustrates additional features of the interface elements surrounding the object core. A scan chain input 1730 provides data into three configuration registers: A core register for configuring the core logic; a Party Line register for configuring the Party Line communications structures; and a programming register for user programming of the core logic, or to load memories for certain types of objects. Some or all of these features can be configured at start-up of the device. Preferably, there are a series of scan chains that collectively program all of the objects within the array and all of the logic blocks in the periphery. A serial string of information is clocked through these various chains with an assigned destination at a particular object. For instance, as the user has constructed an application or a program for the chip, that program defines the settings of the party lines, that is, how each individual object is intended to communicate with its neighbors and the rest of the array, and the particular functions that that object is to perform. Those pieces of information are serially clocked through these scan chains and reach these destination registers that then configure each particular object as desired. Multiple scan chains preferably are implemented so that no one chain has to snake through all of the objects. FIG. 12 also shows a control object in the donut region to receive control input signals. Examples are Initialize, Hold and BIST (built-in self-test) signals. This should not be confused with the periphery block described with reference to FIG. 18.

### FPOA Device Peripheral Region

As noted, the circuitry of the FPOA resides generally in two areas: the core region and the periphery region. The core objects, i.e. silicon objects located within the core region, do most of the computational work, while periphery blocks, i.e., circuits located within the periphery region, can provide additional RAM, move data between core objects and external devices, and implement various other tasks and features.

Referring now to FIG. 18, a simplified, conceptual diagram illustrates a field-programmable object array (FPOA) 2500, showing a core region 2504 and a periphery region 2508. Any desired number of core objects can be implemented in the core region 2504 as further explained later. In this example, the core objects are arranged in a regular square pattern. The objects could be rectangular or any other polygon. The overall core region 2504 need not be square or rectangular either; its actual shape may depend in part on the relevant library of core objects to be implemented.

Subject to space and power limitations, any desired set of periphery objects can be implemented as well. As further explained below, periphery objects provide for field programming of the FPOA, external memory interface, and other external communications. Periphery objects interact with external devices and can provide additional RAM for the core objects. By way of illustration and not limitation, examples of periphery objects may include the following:
Internal RAM (IRAM) (2520 in FIG. 18)′ In one embodiment, each IRAM object provides access to a 2 k by 76-bit (4*16 data bits+4*3 tag bits) SRAM. This SRAM can be preloaded during initialization. There are 12 IRAM objects in the periphery in the illustrated embodiment.
External RAM (XRAM)′ A detailed example of an XRAM controller is given below with reference to FIGS. 28A and 28B. Two are shown in FIG. 18.
Transmit (TX) Interface (2510, 2512 in FIG. 18)′ The TX interface is used for parallel LVDS output from the FPOA.
General Purpose I/O (GPIO)
Receive (RX) Interface (2516, 2518 in FIG. 18)′ The RX interface may be used for parallel LVDS input to the FPOA. In one example, each interface has a 17-bit input (16 data bits+1 tag bit). There are two RX interfaces in the periphery in a presently preferred embodiment, but these numbers are not critical.

FIG. 18 also shows the following three interfaces involved in initialization and control in a presently preferred embodiment:
PROM interface 2530′ The PROM controller oversees the loading and initialization process of the FPOA. It requests data directly from an external PROM until all of the memory and configuration registers are initialized.
JTAG controller 2532′ The JTAG controller provides an alternate way to load an FPOA configuration. It also provides memory to load internal registers for debug purposes.
Control object 2534′ This object can be used to stop the core clock. It also contains a PLL, which multiplies an external reference clock to generate the FPOA core clock.

To summarize some important aspects of the invention, in a preferred embodiment, synchronous communications are provided by way of a homogenous interface with fixed dimensions, a fixed shape, and fixed pinout layout. However, as noted, these limitations are too restrictive. In other embodiments, other sizes and shapes can be used. What is key is the logical or functional connections among core objects (and with periphery blocks in some cases) as described herein. In some embodiments, a peripheral structure referred to as a “donut” is arranged to interface with the object logic, and to implement configurable communications between the local object logic and external objects. By clocking communications through the communications donut, timing is deterministic and predictable. Moreover, the donut provides a standardized interface for placing object logic and for realizing reconfigurable interconnection schemes.

Additionally, the donut structure in a preferred embodiment includes a clock ring, which extends through all of the registers of the donut, providing a mechanism for automatic timing and closed layout construction with automatic clock generation. The present invention provides a number of advantages over the prior art. The basic building block preferably has fixed dimension, fixed shape and fixed pinout and layout, facilitating object logic reuse. The logical elements for each building block may be programmable or fixed, and may include various standard silicon object or user defined silicon objects. The internal and external interface is a standardized reconfigurable interconnect fabric (donut). The donut is synchronous. The peripheral blocks share the same donut interface. The donut includes a power grid and a clock ring distribution. The silicon objects in an array of silicon objects may be connected through their communications donuts by abutment in a simple circuit layout. The clock skew requirement, architecturally speaking, is tight in neighboring building blocks and loose in global scope. A clock tree is a scalable symmetric structure. Clock distribution is regular and balanced with each building block. The donut is designed using standard ASIC or custom techniques, although the latter is preferable for performance and chip area. The design cost and time for the donut is amortized across all designs because the one design can be reused in all building blocks and, therefore, all subsequent designs.

Because the reconfigurable donut is synchronous, the construction of the design using these building blocks requires no timing closure. Preferably, the reconfigurable communications donut is a structure with straight edges, such as a rectangle, triangle, octagon, pentagon, hexagon, and the like. Straight edges make abutment interconnections simple to implement, while maximizing layout density. Additionally, because of the synchronous reconfigurable donut, the programmable or configurable element of the interconnect network is forward compatible to future-developed semiconductor processes. No further timing closure is required except with the redesign of each building block. Thus, the timing closure is limited to individual building blocks and not the overall design.

In one embodiment, the present invention is a silicon object comprised of a homogenous communications structure and object logic mapped into the homogenous communication structure. The homogenous communications structure is comprised of communications elements and interconnections surrounding an object logic area, some of which interconnections extend to peripheral edges of the homogenous communications structure in a standard layout that is repeated for each homogenous communications structure in an array of silicon objects. Interconnections between silicon objects in the array may be completed by abutment or by wiring. A clock bus is provided within the homogenous communications structure to synchronize at least some of the communications elements. The clock bus layout is standardized across all homogenous communication structures in the array. The clock bus includes at least one buffer and a wire segment extending from the at least one buffer to the peripheral edge of the homogenous communication structure to facilitate wiring interconnections between clock buses of adjacent silicon objects.

Although the present invention has been described with reference to preferred embodiments, workers skilled in the art will recognize that changes may be made in form and detail without departing from the spirit and scope of the invention. It will be obvious to those having skill in the art that many changes may be made to the details of the above-described embodiments without departing from the underlying principles of the invention. The scope of the present invention should, therefore, be determined only by the following claims.

1. A field-programmable, semiconductor integrated circuit device comprising:
a core region and a chip periphery region generally surrounding the core region;
and an array of core objects disposed within the core region;
wherein each core object includes both logic circuitry and communication elements for communicating signals with other elements of the device; and
the core object communication elements are operable so as to form any desired communication connection between a selected core object in the array and a second core object in the array.

2. A field-programmable, semiconductor integrated circuit device according to claim 1 wherein all of the core objects in the array have a consistent rectilinear shape so as to enable insertion of the core objects into the array via abutment.

3. A field-programmable, semiconductor integrated circuit device according to claim 2 wherein the logic circuitry in each of the core objects implements a logical function or operation, either independently or cooperatively with other core objects in the array.

4. A field-programmable, semiconductor integrated circuit device according to claim 2 wherein the core objects are configurable so as to define a selected cluster of core objects.

5. A field-programmable, semiconductor integrated circuit device according to claim 4 and operable for routing a RESET signal from the periphery region to the defined cluster of core objects.

6. A field-programmable, semiconductor integrated circuit device according to claim 2 wherein external control of core object start/stop and reset functions are performed by interfacing to the periphery region, which in turn interfaces to the core region.

7. A field-programmable, semiconductor integrated circuit device according to claim 2 wherein the communication elements of a current core object include:
first communication elements for implementing communications between the current core object and adjacent neighbor objects, and
second communication elements for implementing communications between the current core object and non-adjacent core objects.

8. A field-programmable, semiconductor integrated circuit device according to claim 7 wherein the second communication elements of multiple core objects together form an inter-object communication fabric by abutting insertion into the array.

9. A field-programmable, semiconductor integrated circuit device according to claim 8 wherein the communication fabric is formed by said abutting insertion of the core objects without regard the particular logic circuitry implemented in the core objects.

10. A field-programmable, semiconductor integrated circuit device according to claim 8 and further comprising at least one periphery block located within the periphery region of the device, the periphery block coupled to at least one of the first and second communication elements of a core object so as to extend the communication fabric from the core region into the periphery block.

11. A field-programmable, semiconductor integrated circuit device according to claim 10 wherein at least one edge of the periphery block implements a connection to one of the first and second communication elements of a core object so as to extend the communication fabric from the core region into the periphery block by abutting contact between the periphery block and the said core object.

12. A field-programmable, semiconductor integrated circuit device according to claim 10 including a plurality of periphery blocks and wherein at least two of the periphery blocks implement nearest neighbor connections for communication between said periphery blocks.

13. A field-programmable, semiconductor integrated circuit device according to claim 2 wherein each core object further includes resources to support distribution of global control signals between core objects.

14. A field-programmable, semiconductor integrated circuit device comprising:
a core region and a periphery region generally surrounding the core region;
an array of core objects disposed within the core region, wherein each core object includes both logic circuitry and communication elements, the core objects operable in combination so as to form an configurable communication fabric by abutting insertion of the core objects into the array; and
at least one periphery block disposed within the periphery region, wherein the periphery block is coupled to at least one of the communication elements of a core object so as to provide a communication connection between the periphery block and the core object.

15. A field-programmable, semiconductor integrated circuit device according to claim 14 wherein the core region and the periphery block are arranged to receive a common clock signal so that the said communication connection between the core region and the periphery block is synchronous.

16. A field-programmable, semiconductor integrated circuit device according to claim 14 wherein all of the core objects are driven in response to the common clock signal so that the array of core objects is substantially synchronous.

17. A field-programmable, semiconductor integrated circuit device according to claim 14 wherein each core object supports distribution of the common clock signal to at least one adjacent core object by abutment, so that the core objects in the array together distribute the common clock signal throughout the array without intervening structures between core objects.

18. A field-programmable, semiconductor integrated circuit device according to claim 14 wherein each core object supports communications between non-adjacent core objects by abutment, so that the core objects in the array together form a communication fabric throughout the array without intervening structures between core objects.

19. A field-programmable, semiconductor integrated circuit device according to claim 14 wherein each core object includes launch and land registers to support synchronous communication between non-adjacent core objects.

20. A field-programmable, semiconductor integrated circuit device comprising:
a core region and a periphery region generally surrounding the core region;
an array of core objects disposed within the core region; and
a plurality of periphery blocks disposed within the periphery region;
wherein each core object includes both logic circuitry and configurable communication structures arranged so that the core objects together form a configurable communication fabric by abutting placement of the objects in the array; and wherein
at least one of the periphery blocks includes a communication interface structure arranged for connection to said communication structure of at least one of the core objects so as to extend the configurable communication fabric to the periphery block.

21. A field-programmable, semiconductor integrated circuit device according to claim 20 wherein at least one core object is coupled to a periphery block via the communication fabric so as to provide an I/O connection to the device.

22. A field-programmable, semiconductor integrated circuit device according to claim 20 wherein:
the core object communication structures implement a party line signal connection;
the periphery block communication interface structure implements a corresponding party line signal connection; and
the periphery block is arranged so that the periphery block will be coupled to the core region via the party line signal connection when the periphery block is disposed in the periphery region abutting one of the core objects.

23. A field-programmable, semiconductor integrated circuit device according to claim 20 including a clock source to provide a first clock signal, and wherein:
the core object communication structures are operable responsive to the first clock signal; and
the periphery block communication interface structure is operable responsive to the first clock signal, so that the party line signal connection coupling the periphery block to the core region is synchronous to the first clock signal.

24. A field-programmable, semiconductor integrated circuit device according to claim 20 wherein:
the core object communication structures implement a nearest neighbor signal connection;
the periphery block communication interface structure implements a corresponding nearest neighbor signal connection; and
the periphery block is arranged so that the periphery block will be coupled to the core region via the nearest neighbor signal connection when the periphery block is disposed in the periphery region abutting one of the core objects.

25. A field-programmable, semiconductor integrated circuit device according to claim 20 wherein the periphery region includes at least one periphery block for field programming of the device.

26. A field-programmable, semiconductor integrated circuit device according to claim 20 wherein the periphery region includes first and second periphery blocks, each periphery block including communication structures arranged to provide communication between the said periphery blocks that is asynchronous to the core region.

27. A field-programmable, semiconductor integrated circuit device according to claim 26 wherein the periphery block communication structures implement a configurable, segmented parallel communication bus.

28. A field-programmable, semiconductor integrated circuit device according to claim 26 wherein the first and second periphery blocks are positioned adjacent to one another and the said periphery block communication structures implement a nearest neighbor connection between the said periphery blocks.

29. A field-programmable, semiconductor integrated circuit device comprising:
a core region and a periphery region generally surrounding the core region;
including an array of core objects disposed in the core region, wherein:
each core object includes both logic circuitry and means for communicating signals with adjacent core objects in the array;
and the communicating means in a current core object of the array implements a signal connection between a second core object, positioned adjacent to the current core object, and a third core object, also positioned adjacent to the current core object so as to provide a neighbor connection in which the current core object has no logical involvement.

30. A device according to claim 29 wherein the said neighbor connection imposes substantially no latency.

31. A device according to claim 29 wherein the said signal connection enables the second core object to read a result register of the third core object.

32. A device according to claim 29 wherein the said signal connection remains operable while power is not supplied to the current core object logic circuitry.

33. A device according to claim 29 wherein the array defines a rectilinear grid pattern and the second and third core objects are positioned diagonally adjacent to one another in the grid pattern.

34. A device according to claim 29 wherein the current core object includes a result register that is readable by at least one of the second and third core objects to provide input signals to the corresponding core logic circuitry.

35. A device according to claim 29 wherein the objects are physically rectilinear and have a common size, thereby defining a total of eight neighboring objects adjacent to the current core object.

36. A field-programmable, semiconductor integrated circuit device comprising:
a core region and a periphery region generally surrounding the core region;
an array of core objects disposed within the core region, wherein each core object includes both logic circuitry and communication elements, the core objects arranged so that the core objects together form an configurable communication fabric by abutting insertion of the core objects into the array; and
at least one periphery block disposed within the periphery region, wherein the periphery block is coupled to at least one of the communication elements of a core object so as to provide a communication connection between the periphery block and the core object; and
wherein each core object includes a scan chain register arranged for receiving external information and a scan chain output for routing the external information to an adjacent object so that a series of core objects together form a serial scan chain.

37. A field-programmable, semiconductor integrated circuit device according to claim 36 wherein the scan chain registers are arranged so that a serial scan chain is formed by abutting arrangement of the core objects without regard to the specific logic circuitry implemented in the core objects.

38. A field-programmable, semiconductor integrated circuit device according to claim 37 wherein the serial scan chain is coupled to a periphery block to receive the external information.

39. A method for ensuring deterministic timing in the design of an FPOA having an array of core objects, the timing method comprising:
providing a common clock signal in or to the FPOA;
coupling all of the core objects in the array to the common clock signal so that operation of the core objects is synchronized at least within a predefined hop distance among the core objects;
configuring communication paths between remote objects of the array as required for a given application of the FPOA; and
in configuring said communication paths between said remote objects, configuring each said communication path so as to latch the communication path signals within the predefined hop distance from the source.

40. A method according to claim 39 wherein the hop distance is determined as a function of the frequency of the common clock signal.

41. A field-programmable, semiconductor integrated circuit device comprising:
a core region and a periphery region generally surrounding the core region;
an array of core objects disposed within the core region;
wherein each core object includes both logic circuitry and communication elements operable for communicating signals with other core objects in the array; and
wherein the logic circuitry of at least one of the core objects can be selectively switched on and off without affecting the communication elements so that the communication elements remain operable as part of a communications fabric formed by the objects in the array.

42. A field-programmable, semiconductor integrated circuit device according to claim 41 wherein a predetermined portion of the logic circuitry of at least one core object can be selectively switched on and off without affecting the remainder of the logic circuitry of said core object.

43. A field-programmable, semiconductor integrated circuit device comprising:
a core region and a periphery region generally surrounding the core region;
and an array of core objects disposed within the core region; and wherein—
each core object includes both logic circuitry and interface elements for interfacing with other elements of the device;
the core object interface elements are configurable so as to form a desired communication path between any selected core object in the array and any second core object in the array without modifying the design of the core objects; and
the core object interface elements comply with a predetermined standard physical layout that includes connections that extend to predetermined locations along at least one peripheral edge of the core object so as to implement interface connections to an adjacent core object by physical abutment of the objects without regard to the specific design of the logic circuitry of the core objects.

44. A field-programmable, semiconductor integrated circuit device according to claim 43 wherein the interface elements are operable to distribute at least one of power, clock and communication signals.

45. A field-programmable, semiconductor integrated circuit device according to claim 43 wherein each core object includes a donut region generally surrounding the logic circuitry, and the interface elements are disposed in the donut region.

46. A field-programmable, semiconductor integrated circuit device according to claim 43 wherein the interface elements of each core object include communication elements and the communication elements of the array together form a communications fabric by said physical abutment of the core objects.

47. A field-programmable, semiconductor integrated circuit device according to claim 43 wherein each core object includes a donut region generally surrounding the logic circuitry, and the core object communication elements are disposed in the donut region.

48. A field-programmable, semiconductor integrated circuit device according to claim 43 wherein:
the periphery region includes at least one periphery block;
and the periphery block includes a communication element that interfaces with a communication element of a core object positioned along a peripheral edge of the array abutting the periphery region.

49. A field-programmable, semiconductor integrated circuit device according to claim 43 wherein each core object further includes resources to support distribution of global control signals between core objects without modifying a design of the core object.
